(19) United States
(12) Patent Application Publication
(10) Pub. No.: US 2026/0181753 A1
(43) Pub. Date: Jun. 25, 2026

(54) CONTROL CHIP AND SYSTEM

(71) Applicant: Nuvoton Technology Corporation, Hsinchu Science Park (TW)

(72) Inventors: Shih-Chieh LEE, New Taipei City (TW); Chieh-Sheng TU, Hsinchu Science Park (TW); Chang-Hong LIN, Taichung City (TW); Ya-Han CHIEN, Hsinchu City (TW)

(21) Appl. No.: 19/409,049

(22) Filed: Dec. 4, 2025

(30) Foreign Application Priority Data
Dec. 25, 2024 (TW) 113150538

(51) Int. Cl. H05B 45/14; G06F 13/12; H05K 1/181

(52) U.S. Cl. CPC H05B 45/14; G06F 13/12; H05K 1/181; H05K 2201/10106

(57) ABSTRACT

A control chip disposed in a motherboard and including a first detection pin, a second detection pin, a first control pin, a second control pin, a detection circuit and a determination circuit is provided. The first detection pin is coupled to a first external device including a first light-emitting circuit. The second detection pin is coupled to a second external device including a second light-emitting circuit. The first and second control pins are respectively coupled to the first and second light-emitting circuits. The detection circuit detects the voltages of the first and second detection pins to generate a first detection signal and a second detection signal. In response to the first external device having been coupled to the motherboard and the second external device having been coupled to the motherboard, the determination circuit controls the lighting effects displayed by the first and second light-emitting circuits.

### CROSS REFERENCE TO RELATED APPLICATIONS

This Application claims priority of Taiwan Patent Application No. 113150538, filed on Dec. 25, 2024, the entirety of which is incorporated by reference herein.

### TECHNICAL FIELD

The present disclosure relates to a control chip, and, in particular, it relates to a control chip for controlling a plurality of light-emitting circuits.

### BACKGROUND

To meet the requirements of the esports market, many peripheral devices have lighting functions. Different peripheral devices use different clock signals to control lighting effects. When different peripheral devices are integrated into the same system, a time difference in lighting effects gradually appears because the clock signals of the various peripheral devices are not synchronized. Furthermore, it is difficult for the lighting effects of different peripheral devices to be interactive.

### BRIEF SUMMARY

An embodiment of the present disclosure provides a control chip which is disposed in a motherboard. The control chip comprises a first detection pin, a second detection pin, a first control pin, a second control pin, a detection circuit and a determination circuit. The first detection pin is coupled to a first external device comprising a first light-emitting circuit. The second detection pin is coupled to a second external device comprising a second light-emitting circuit. The first control pin is coupled to the first light-emitting circuit. The second control pin is coupled to the second light-emitting circuit. The detection circuit detects the voltage of the first detection pin to generate a first detection signal and detects the voltage of the second detection pin to generate a second detection signal. The determination circuit determines whether the first external device is coupled to the motherboard and determines whether the second external device is coupled to the motherboard. In response to the first external device having been coupled to the motherboard and the second external device having been coupled to the motherboard, the determination circuit provides a first lighting-effect command to the first control pin and provides a second lighting-effect command to the second control pin. The first light-emitting circuit displays a first lighting effect according to the first lighting-effect command. The second light-emitting circuit displays a second lighting effect according to the second lighting-effect command.

An embodiment of the present disclosure provides a control system which comprises a motherboard and a control chip. The control chip is disposed on the motherboard and comprises a first detection pin, a second detection pin, a first control pin, a second control pin, a detection circuit, and a determination circuit. The first detection pin is coupled to a first external device which comprises a first light-emitting circuit. The second detection pin is coupled to a second external device which comprises a second light-emitting circuit. The first control pin is coupled to the first light-emitting circuit. The second control pin is coupled to the second light-emitting circuit. The detection circuit detects the voltage of the first detection pin to generate a first detection signal and detects the voltage of the second detection pin to generate a second detection signal. The determination circuit determines whether the first external device is coupled to the motherboard and determines whether the second external device is coupled to the motherboard. In response to the first external device having been coupled to the motherboard and the second external device having been coupled to the motherboard, the determination circuit provides a first lighting-effect command to the first control pin and provides a second lighting-effect command to the second control pin. The first light-emitting circuit displays a first lighting effect according to the first lighting-effect command. The second light-emitting circuit displays a second lighting effect according to the second lighting-effect command.

In addition, an embodiment of the present disclosure provides a control system comprising a first external device, a second external device, a motherboard, and a control chip. The first external device comprises a first light-emitting circuit. The second external device comprises a second light-emitting circuit. The motherboard is coupled to the first external device and the second external device. The control chip is disposed on the motherboard and comprises a first detection pin, a second detection pin, a first control pin, a second control pin, and a control circuit. The first detection pin is coupled to the first external device. The second detection pin is coupled to the second external device. The first control pin is coupled to the first light-emitting circuit. The second control pin is coupled to the second light-emitting circuit. The control circuit detects whether the first external device is coupled to the first detection pin and detects whether the second external device is coupled to the second detection pin. In response to the first external device having been coupled to the first detection pin and the second external device having been coupled to the second detection pin, the control circuit assigns a first lighting-effect command to the first control pin and assigns a second lighting-effect command to the second control pin. The first light-emitting circuit displays a first lighting effect according to the first lighting-effect command. The second light-emitting circuit displays a second lighting effect according to the second lighting-effect command.

### BRIEF DESCRIPTION OF THE DRAWINGS

The present disclosure can be more fully understood by reading the subsequent detailed description and examples with references made to the accompanying drawings, wherein:

FIG. 1A is a schematic diagram of an exemplary embodiment of a control system according to various aspects of the present disclosure;

FIG. 1B is a schematic diagram of another exemplary embodiment of the control system according to various aspects of the present disclosure;

FIG. 2A is a schematic diagram of an exemplary embodiment of the lighting effects displayed by the light-emitting circuits according to various aspects of the present disclosure;

FIG. 2B is a schematic diagram of another exemplary embodiment of the lighting effects displayed by the light-emitting circuits according to various aspects of the present disclosure; and

FIG. 3 is a schematic diagram of an exemplary embodiment of a control circuit according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

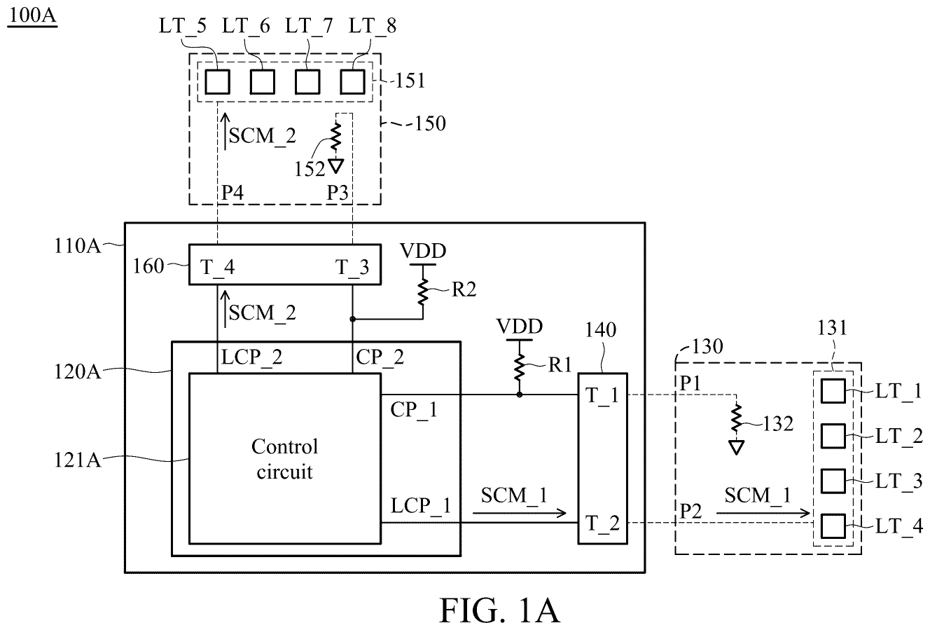

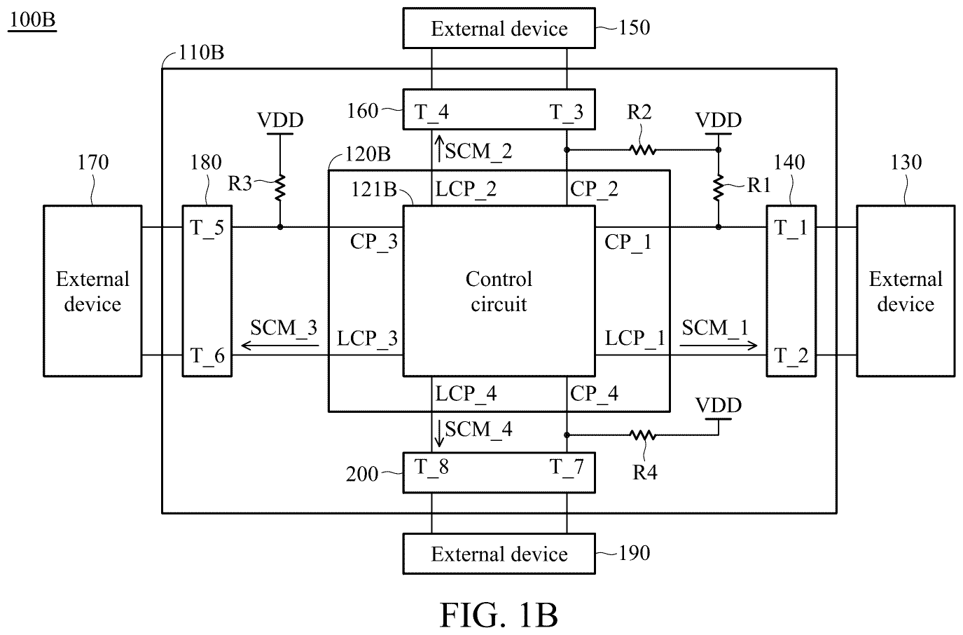

FIG. 1A is a schematic diagram of an exemplary embodiment of a control system according to various aspects of the present disclosure. The control system 100A comprises a motherboard 110A and a control chip 120A. In one embodiment, the control chip 120A is disposed on the motherboard 110A and comprises detection pins CP_1 and CP_2, control pins LCP_1 and LCP_2, and a control circuit 121A.

The detection pin CP_1 is coupled to an external device 130. In this embodiment, the control system 100A further comprises a slot 140. The slot 140 is disposed on the motherboard 110A. The detection pin CP_1 is indirectly coupled to the external device 130 via the slot 140. The detection pin CP_1 is electrically connected to the contact pad T_1 of the slot 140. When the external device 130 inserts into the slot 140, the pin P1 of the external device 130 is electrically connected to the contact pad T_1 of the slot 140.

The external device 130 comprises pins P1 and P2, and a light-emitting circuit 131. When the external device 130 inserts into the slot 140, the pin P1 is electrically connected to the contact pad T_1 and the pin P2 is electrically connected to the contact pad T_2. The light-emitting circuit 131 is coupled to the pin P2 to receive a lighting-effect command SCM_1. The light-emitting circuit 131 displays a lighting effect (e.g., an inhalation lighting effect or a water ripple lighting effect) according to the lighting-effect command SCM_1. The circuit structure of the light-emitting circuit 131 is not limited in the present disclosure. In one embodiment, the light-emitting circuit 131 is a light-emitting strip. In this embodiment, the light-emitting circuit 131 comprises light-emitting elements LT_1˜LT_4, but the disclosure is not limited thereto. In other embodiments, the light-emitting circuit 131 comprises the more or the fewer light-emitting elements. In one embodiment, the light-emitting elements LT_1˜LT_4 are light-emitting diodes (LEDs). The light-emitting circuits 131 controls the emission time and color of the light-emitting elements LT_1˜LT_4 according to the lighting-effect command SCM_1.

The type of external device 130 is not limited in the present disclosure. In one embodiment, the external device 130 is a memory module, such as a dual in-line memory module (DIMM). In this case, the external device 130 further comprises a storage circuit (not shown) and a plurality of access pins (not shown). The storage circuit receives and stores data from the motherboard 110A or outputs data to the motherboard 110A via the access pins. In some embodiments, the motherboard 110A comprises a specific chip (not shown) for accessing the external device 130. The specific chip (such as a CPU) connects to the access pins of the external device 130 via other contact pads of the slot 140. In this case, the slot 140 is a memory slot.

In another embodiment, the external device 130 comprises a heat dissipation device, such as a fan. In this case, the external device 130 has other control pins for receiving control commands from the motherboard 110A and adjusting the speed of the fan according to the control commands. In some embodiments, the control circuit 121A generates a lighting-effect command SCM_1 according to the speed of the fan, so that the lighting effect displayed by the light-emitting circuit 131 changes with the speed of the fan. In some embodiments, the external device 130 is a housing, such as a computer case. In this case, the motherboard 110A is disposed in the housing.

The detection pin CP_2 is coupled to an external device 150. In this embodiment, the control system 100A further comprises a slot 160. The slot 160 is disposed on the motherboard 110A. The detection pin CP_2 is indirectly coupled to the external device 150 via the slot 160. In one embodiment, the detection pin CP_2 is electrically connected to the contact pad T_3 of the slot 160. When the external device 150 inserts into the slot 160, the pin P3 of the external device 150 is electrically connected to the contact pad T_3 of the slot 160.

The external device 150 comprises pins P3 and P4, and a light-emitting circuit 151. When the external device 150 inserts into the slot 160, the pin P3 is electrically connected to the contact pad T_3 and the pin P4 is electrically connected to the contact pad T_4. The light-emitting circuit 51 is coupled to the pin P4 to receive a lighting-effect command SCM_2. In this embodiment, the light-emitting circuit 151 displays a lighting effect according to the lighting-effect command SCM_2. Since the characteristics of the light-emitting circuit 151 are similar to the characteristics of the light-emitting circuit 131, the related description is omitted here.

Since the characteristics of the external device 150 are similar to the characteristics of the external device 130, the related description is omitted here. In some embodiments, the structure of the external device 130 is the same as the structure of the external device 150. For example, the external devices 130 and 150 are memory modules. In another embodiment, the structure of the external device 130 is different from the structure of the external device 150. For example, the external device 130 comprises a fan and the external device 150 comprises a computer case.

The control pin LCP_1 is coupled to the light-emitting circuit 131 of the external device 130 and transmits the lighting-effect command SCM_1. When the external device 130 inserts into the slot 140, the pin P2 is electrically connected to the contact pad T_2. The control pin LCP_1 provides the lighting-effect command SCM_1 to the light-emitting circuit 131 via the contact pad T_2.

The control pin LCP_2 is coupled to the light-emitting circuit 151 of the external device 150 and transmits the lighting-effect command SCM_2. When the external device 150 inserts into the slot 160, the pin P4 is electrically connected to the contact pad T_4. The control pin LCP_2 provides the lighting-effect command SCM_2 to the light-emitting circuit 151 via the contact pad T_4.

The number of detection pins and control pins are not limited in the present disclosure. In other embodiments, the control chip 120A comprises the more detection pins and the more control pins to control the lighting effects of more external devices. In this embodiment, the control circuit 121A determines whether the external device 130 is coupled to the motherboard 110A according to the voltage of the detection pin CP_1 and determines whether the external device 150 is coupled to the motherboard 110A according to the voltage of the detection pin CP_2.

For example, when the voltage of the detection pin CP_1 is equal to a first predetermined voltage, it means that the external device 130 has been coupled to the motherboard 110A. Therefore, the control circuit 121A generates the lighting-effect command SCM_1 to the control pin LCP_1. When the voltage of the detection pin CP_1 is not equal to the first predetermined voltage, it means that the external device 130 is not coupled to the motherboard 110A. Therefore, the control circuit 121A stops generating the lighting-effect command SCM_1.

Similarly, when the voltage of the detection pin CP_2 is equal to a second predetermined voltage, it means that the external device 150 has been coupled to the motherboard 110A. Therefore, the control circuit 121A generates the lighting-effect command SCM_ to the control pin LCP_2. When the voltage of the detection pin CP_2 is not equal to the second predetermined voltage, it means that the external device 150 is not coupled to the motherboard 110A. Therefore, the control circuit 121A stops generating the lighting-effect command SCM_2.

The first predetermined voltage may be the same as or different from the second predetermined voltage. The control circuit 121A determines the connection status between the external device 130 and the motherboard 110A according to the voltage of the detection pin CP_1 and determines the connection status between the external device 150 and the motherboard 110A according to the voltage of the detection pin CP_2. The control circuit 121A generates the corresponding lighting-effect command according to the corresponding connection status. For example, when the external device 130 is coupled to the motherboard 110A, the control circuit 121A utilizes the lighting-effect command SCM_1 to direct the light-emitting circuit 131 to display a first lighting effect. At this time, if the external device 150 is coupled to the motherboard 110A, the control circuit 121A utilizes the lighting-effect command SCM_2 to direct the light-emitting circuit 151 to display a second lighting effect and further utilizes the lighting-effect command SCM_1 to direct the light-emitting circuit 131 to display a third lighting effect. In other words, when external device 130 is coupled to the motherboard 110A alone, the lighting effect displayed by the light-emitting circuit 131 may be different from or the same as the lighting effect displayed by the light-emitting circuit 131 when external devices 130 and 150 are coupled to the motherboard 110A simultaneously.

In some embodiments, when external devices 130 and 150 are coupled to the motherboard 110A simultaneously, the control circuit 121A utilizes the lighting-effect commands SCM_1 and SCM_2 to synchronize the lighting effects displayed by the light-emitting circuits 131 and 151. In another embodiment, the lighting effects displayed by the light-emitting circuits 131 and 151 have an interactive effect, such as a chain lighting effect. In other words, the light-emitting circuit 131 operates first, followed by the light-emitting circuit 151. When the light-emitting circuit 131 operates, the light-emitting circuit 151 stops operating. When the light-emitting circuit 151 operates, the light-emitting circuit 131 pauses operating. For example, the light-emitting elements LT_1˜LT_4 are lit sequentially. In this case, after the light-emitting element LT_4 is lit, the light-emitting elements LT_5˜LT_8 are lit sequentially.

In other embodiment, the control circuit 121A determines the type of the external device 130 according to the voltage of the detection pin CP_1 and determines the type of the external device 150 according to the voltage of the detection pin CP_2. Taking the detection pin CP_1 as an example, when the voltage of the detection pin CP_1 is equal to a first specific voltage, it indicates that that external device 130 is a first type external device, such as a memory module. When the voltage of the detection pin CP_1 is equal to a second specific voltage, it indicates that the external device 130 is a second type external device, such as a fan. When the voltage of the detection pin CP_1 is equal to a third specific voltage, it indicates that the external device 130 is a third type external device, such as a housing. The control circuit 121A generates the lighting-effect command SCM_1 according to the type of the external device 130 and the lighting-effect command SCM_2 according to the type of the external device 150.

In other embodiments, the control system 100A further comprises resistors R1 and R2. The resistors R1 and R2 are disposed on the motherboard 110A and outside of the control chip 120A, but the disclosure is not limited thereto. In other embodiments, the resistors R1 and R2 are integrated into the control chip 120A. In this embodiment, the resistor R1 receives the operating voltage VDD and is coupled to the detection pin CP_1. The resistor R2 receives the operating voltage VDD and is coupled to the detection pin CP_2.

Taking the detection pin CP_1 as an example, when the voltage of the detection pin CP_1 is equal to the operating voltage VDD, it means that the external device 130 is not coupled to the motherboard 110A. Therefore, the control circuit 121A does not generate the lighting-effect command SCM_1. When the voltage of the detection pin CP_1 is not equal to the operating voltage VDD, it means that the external device 130 is coupled to the motherboard 110A. Therefore, the control circuit 121A starts generating the lighting-effect command SCM_1.

In some embodiment, the external device 130 further comprises a resistor 132. When the external device 130 inserts into the slot 140, since the resistor R1 is connected to the resistor 132 in series, the voltage of the detection pin CP_1 is equal to a first divided voltage. Additionally, the resistor 132 of different types of external devices has different resistance values. In this case, the control circuit 121A can determine the type of external device 130 according to the voltage of the detection pin CP_1.

Similarly, the external device 150 further comprises a resistor 152. When the external device 150 inserts into the slot 160, since the resistor R2 is connected to the resistor 152 in series, the voltage of the detection pin CP_2 is equal to a second divided voltage. The second divided voltage may be the same as or different from the first divided voltage. For example, when the type of the external device 130 is the same as the type of the external device 150, the first divided voltage may be equal to the second divided voltage. When the type of the external device 130 is different from the type of the external device 150, the first divided voltage is not equal to the second divided voltage.

FIG. 1B is a schematic diagram of another exemplary embodiment of the control system according to various aspects of the present disclosure. FIG. 1B is similar to FIG. 1A with the exception that the control chip 120B further comprises detection pins CP_3 and CP_4, and the control pins LCP_3 and CLP_4. The control circuit 121B determines whether the external device 170 has been coupled to the motherboard 110B according to the voltage of the detection pin CP_3 and determines whether the external device 190 has been coupled to the motherboard 110B according to the voltage of the detection pin CP_4. When the external device 170 has been coupled to the motherboard 110B, the control circuit 121B uses the control pin LCP_3 to provide a lighting-effect command SCM_3 to the external device 170. The lighting effect displayed by a light-emitting circuit (not shown) of the external device 170 is controlled by the control circuit 121B. When the external device 190 has been coupled to the motherboard 110B, the control circuit 121B uses the control pin LCP_4 to provide a lighting-effect command SCM_4 to the external device 190. The lighting effect displayed by a light-emitting circuit (not shown) of the external device 190 is controlled by the control circuit 121B. Since the characteristics of the external devices 170 and 190 are similar to the characteristics of the external device 130, the related description is omitted here.

A single control chip 120B controls the lighting effects of multiple light-emitting circuits in multiple external devices, the cost can be saved. Because it is not necessary to dispose a control chip in each external device, the usable space of the external devices can also be increased. Furthermore, the lighting-effect commands issued by the same control chip enable different light-emitting circuits to display synchronized lighting effects. Therefore, the lighting effects of different light-emitting circuits are interactive.

In this embodiment, the motherboard 110B of the control system 100B further comprises slots 180 and 200. The slot 180 is disposed in the motherboard 110B and comprises contact pads T_5 and T_6. The contact pad T_5 is electrically connected to the detection pin CP_3. The contact pad T_6 is electrically connected to the control pin LCP_3. When the external device 170 inserts into the slot 180, the external device 170 is electrically connected to the contact pads T_5 and T_6. The slot 200 is disposed in the motherboard 110B and comprises contact pads T_7 and T_8. The contact pad T_7 is electrically connected to the detection pin CP_4. The contact pad T_8 is electrically connected to the control pin LCP_4. When the external device 190 inserts into the slot 200, the external device 190 is electrically connected to the contact pads T_7 and T_8.

Since the characteristics of the slots 180 and 200 are similar to the characteristics of the slot 140, the related description is omitted here. The types of the slots 140, 160, 180, and 200 are related to the types of the external devices 130, 150, 170, and 190, respectively. In some embodiments, the type of one of the external devices 130, 150, 170, and 190 is different from that of another of the external devices 130, 150, 170, and 190. In this case, the type of one of the slots 140, 160, 180, and 200 is different from that of another of the slots 140, 160, 180, and 200.

In some embodiments, the motherboard 110B further comprises resistors R3 and R4. The resistor R3 receives the operating voltage VDD and is coupled to the detection pin CP_3. The resistor R4 receives the operating voltage VDD and is coupled to the detection pin CP_4. Since the characteristics of the resistors R3 and R4 are similar to the characteristics of the resistor R1, the related description is omitted here.

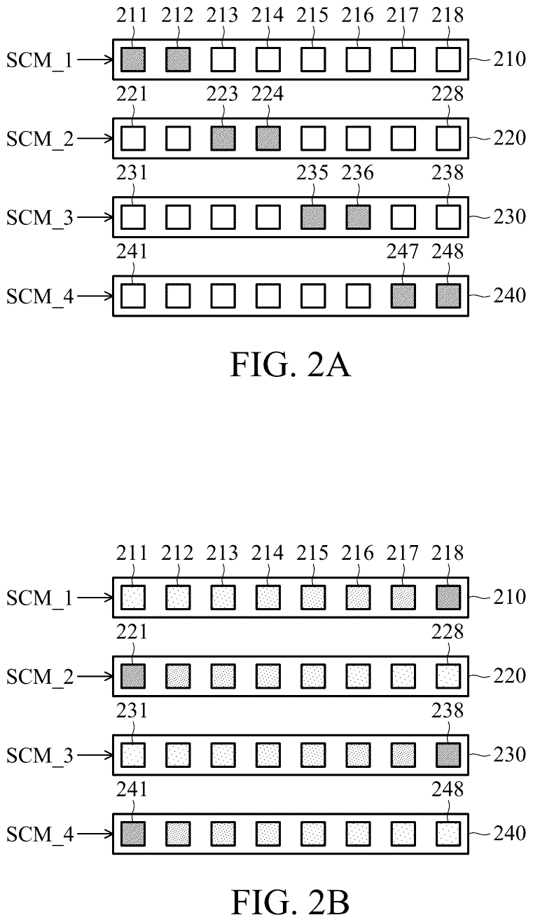

FIG. 2A is a schematic diagram of an exemplary embodiment of the lighting effects displayed by the light-emitting circuits according to various aspects of the present disclosure. Assume that the light-emitting circuits 210, 220, 230, and 240 are disposed in the external devices 130, 150, 170, and 190 shown in FIG. 1B, respectively. The light-emitting circuit 210 controls the light-emitting elements 211˜218 according to the lighting-effect command SCM_1. The light-emitting circuit 220 controls the light-emitting elements 221˜228 according to the lighting-effect command SCM_2. The light-emitting circuit 230 controls the light-emitting elements 231˜238 according to the lighting-effect command SCM_3. The light-emitting circuit 240 controls the light-emitting elements 24˜248 according to the lighting-effect command SCM_4.

In this embodiment, the light-emitting circuits 210, 220, 230, and 240 display interactive lighting effects. For example, during a first period, the light-emitting elements 211 and 212 are illuminated and the remaining light-emitting elements are not illuminated. During a second period, the light-emitting elements 223 and 224 are illuminated and the remaining light-emitting elements are not illuminated. During a third period, the light-emitting elements 235 and 236 are illuminated and the remaining light-emitting elements are not illuminated. During a fourth period, the light-emitting elements 247 and 248 are illuminated and the remaining light-emitting elements are not illuminated.

FIG. 2B is a schematic diagram of another exemplary embodiment of the lighting effects displayed by the light-emitting circuits according to various aspects of the present disclosure. In this embodiment, the light-emitting circuits 210, 220, 230, and 240 display a water ripple lighting effect. For example, the brightness of the light-emitting elements 211˜218 gradually increases and the brightness of the light-emitting elements 221˜228 gradually decreases. The brightness of the light-emitting elements 211˜218 is the same as the brightness of the light-emitting elements 228˜221. In this case, the brightness of the light-emitting elements 211˜218 is the same as the brightness of the light-emitting elements 231˜238, and the brightness of the light-emitting elements 221˜228 is the same as the brightness of the light-emitting elements 241˜248.

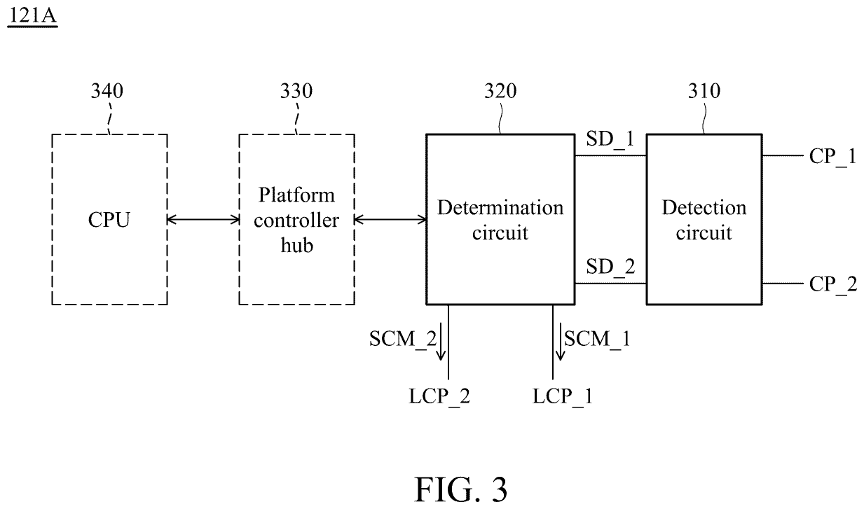

FIG. 3 is a schematic diagram of an exemplary embodiment of a control circuit according to various aspects of the present disclosure. Since the operation of the control circuit 121A is similar to the operation of the control circuit 121B, the control circuit 121A is given as an example in FIG. 3. As shown in FIG. 3, the control circuit 121A comprises a detection circuit 310 and a determination circuit 320. The detection circuit 310 detects the voltage of the detection pin CP_1 to generate a detection signal SD_1 and detects the voltage of the detection pin CP_2 to generate a detection signal SD_2. In some embodiment, when the detection circuit 310 detects the voltages of more detection pins, the detection circuit 310 generates more detection signals.

In one embodiment, the detection circuit 310 detects the voltage of the detection pin CP_1 and determines whether the voltage of the detection pin CP_1 is equal to the first predetermined voltage. When the voltage of the detection pin CP_1 is equal to the first predetermined voltage, it means that the external device 130 has been coupled to the motherboard 110A. Therefore, the detection circuit 310 sets the detection signal SD_1 at a first level, such as a high level. When the voltage of the detection pin CP_1 is not equal to the first predetermined voltage, it means that the external device 130 is not coupled to the motherboard 110A. Therefore, the detection circuit 310 sets the detection signal SD_1 at a second level, such as a low level.

In another embodiment, the detection circuit 310 detects the voltage of the detection pin CP_2 and determines whether the voltage of the detection pin CP_2 is equal to a second predetermined voltage. The second predetermined voltage may be the same as or different from the first predetermined voltage. When the voltage of the detection pin CP_ is equal to a second predetermined voltage, it means that the external device 150 has been coupled to the motherboard 110A. Therefore, the detection circuit 310 sets the detection signal SD_2 at a first level. When the voltage of the detection pin CP_2 is not equal to the second predetermined voltage, it means that the external device 150 is not coupled to the motherboard 110A. Therefore, the detection circuit 310 sets the detection signal SD_2 at a second level.

The determination circuit 320 determines whether the external device 130 has been coupled to the motherboard 110A according to the detection signal SD_1 and whether the external device 150 has been coupled to the motherboard 110A according to the detection signal SD_2. For example, when the detection signal SD_1 is at a first level, it means that the external device 130 has been coupled to the motherboard 110A. Therefore, the determination circuit 320 provides the lighting-effect command SCM_1 to the control pin LCP_1. When the detection signal SD_1 is at a second level, it means that the external device 130 is not coupled to the motherboard 110A. Therefore, the determination circuit 320 stops providing the lighting-effect command SCM_1. Similarly, when detection signal SD_2 is at a first level, it means that the external device 150 has been coupled to the motherboard 110A. Therefore, the determination circuit 320 provides the lighting-effect command SCM_2 to the control pin LCP_2. When detection signal SD_2 is at a second level, it means that the external device 150 has been coupled to the motherboard 110A. Therefore, the determination circuit 320 stops providing the lighting-effect command SCM_2.

In one embodiment, the determination circuit 320 assigns the lighting-effect commands SCM_1 and SCM_2 to different channels (i.e., the control pins LCP_1 and LCP_2) according to a clock signal (not shown). Since the determination circuit 320 uses the same clock signal to control the light-emitting circuits of all external devices, the asynchronous lighting effects between the light-emitting circuits can be avoided and the light-emitting circuits display interactive lighting effects. Furthermore, the determination circuit 320 appropriately controls the lighting effects of the external devices coupled to the motherboard according to the connection statuses between the motherboard and the external devices to provide a better lighting effect. In other embodiments, when the detection circuit 310 provides more detection signals, the determination circuit 320 generates more lighting effect commands to more control pins.

In some embodiments, the control circuit 121A further comprises a platform control hub 330 and a central processing unit (CPU) 340. In this case, the determination circuit 320 provides a connection status between the external device 130 and the motherboard 110A and a connection status between the external device 150 and the motherboard 110A to the CPU 340 via the platform controller hub 330.

In one embodiment, the CPU 340 controls the operations of the external device 130 and 150. Taking the external device 130 as an example, assume that the external device 130 is a memory module. In this case, when the external device 130 is coupled to the motherboard 110A, the CPU 340 may access the external device 130 via the slot 140.

It should be understood that when an element or layer is referred to as being “on”, “connected to” or “coupled to” another element or layer, it can be directly on, connected or coupled to the other element or layer or intervening elements or layers may be present. In contrast, when an element or layer is referred to as be “directly on”, “directly connected to” or “directly coupled to” another element or layer, there are no intervening elements or layers present.

Unless otherwise defined, all terms (including technical and scientific terms) used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and will not be interpreted in an idealized or overly formal sense unless expressly so defined herein. It should be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A control chip disposed in a motherboard, comprising
a first detection pin coupled to a first external device comprising a first light-emitting circuit;
a second detection pin coupled to a second external device comprising a second light-emitting circuit;
a first control pin coupled to the first light-emitting circuit;
a second control pin coupled to the second light-emitting circuit;
a detection circuit detecting a voltage of the first detection pin to generate a first detection signal and detecting a voltage of the second detection pin to generate a second detection signal; and
a determination circuit determining whether the first external device is coupled to the motherboard and determining whether the second external device is coupled to the motherboard,
wherein:
in response to the first external device having been coupled to the motherboard and the second external device having been coupled to the motherboard, the determination circuit provides a first lighting-effect command to the first control pin and provides a second lighting-effect command to the second control pin, and
the first light-emitting circuit displays a first lighting effect according to the first lighting-effect command, and the second light-emitting circuit displays a second lighting effect according to the second lighting-effect command.

2. The control chip as claimed in claim 1, further comprising:
a first resistor coupled to the first detection pin; and
a second resistor coupled to the second detection pin,
wherein:
in response to the voltage of the first detection pin being equal to a first predetermined voltage and the voltage of the second detection pin being equal to a second predetermined voltage, the determination circuit provides the first lighting-effect command to the first control pin and provides the second lighting-effect command to the second control pin.

3. The control chip as claimed in claim 2, wherein the first predetermined voltage is different from the second predetermined voltage.

4. The control chip as claimed in claim 3, wherein:
in response to the voltage of the first detection pin not being equal to the first predetermined voltage, the determination circuit stops providing the first lighting-effect command, and
in response to the voltage of the second detection pin not being equal to the second predetermined voltage, the determination circuit stops providing the second lighting-effect command.

5. A control system, comprising:
a motherboard; and
a control chip disposed on the motherboard and comprising:
a first detection pin coupled to a first external device comprising a first light-emitting circuit;
a second detection pin coupled to a second external device comprising a second light-emitting circuit;
a first control pin coupled to the first light-emitting circuit;
a second control pin coupled to the second light-emitting circuit;
a detection circuit detecting a voltage of the first detection pin to generate a first detection signal and detecting a voltage of the second detection pin to generate a second detection signal; and
a determination circuit determining whether the first external device is coupled to the motherboard and determining whether the second external device is coupled to the motherboard,
wherein:
in response to the first external device having been coupled to the motherboard and the second external device having been coupled to the motherboard, the determination circuit provides a first lighting-effect command to the first control pin and provides a second lighting-effect command to the second control pin,
the first light-emitting circuit displays a first lighting effect according to the first lighting-effect command, and the second light-emitting circuit displays a second lighting effect according to the second lighting-effect command.

6. The control system as claimed in claim 5, further comprising:
a first slot configured to accommodate the first external device; and
a second slot configured to accommodate the second external device,
wherein the first detection pin is electrically connected to the first slot, and the second detection pin is electrically connected to the second slot.

7. The control system as claimed in claim 6, wherein the first slot and the second slot are memory slots.

8. The control system as claimed in claim 6, wherein the first slot comprises:
a first contact pad electrically connected to the first detection pin; and
a second contact pad electrically connected to the first control pin,
wherein:
in response to the first external device being coupled to the first slot, the first contact pad is electrically connected to a first pin of the first external device, and the second contact pad is electrically connected to a second pin of the first external device.

9. The control system as claimed in claim 8, wherein the second slot comprises:
a third contact pad electrically connected to the second detection pin; and
a fourth contact pad electrically connected to the second control pin,
wherein:
in response to the second external device being coupled to the second slot, the third contact pad is electrically connected to a third pin of the second external device, and the fourth contact pad is electrically connected to a fourth pin of the second external device.

10. The control system as claimed in claim 9, further comprising:
a first resistor coupled to the first detection pin; and
a second resistor coupled to the second detection pin,
wherein the first pin is coupled to a third resistor, the third pin is coupled to a fourth resistor, the second pin is coupled to the first light-emitting circuit, and the fourth pin is coupled to the second light-emitting circuit.

11. A control system, comprising:
a first external device comprising a first light-emitting circuit;
a second external device comprising a second light-emitting circuit;
a motherboard coupled to the first external device and the second external device; and
a control chip disposed on the motherboard and comprising:
a first detection pin coupled to the first external device;
a second detection pin coupled to the second external device;
a first control pin coupled to the first light-emitting circuit;
a second control pin coupled to the second light-emitting circuit; and
a control circuit detecting whether the first external device is coupled to the first detection pin and detecting whether the second external device is coupled to the second detection pin,
wherein:
in response to the first external device having been coupled to the first detection pin and the second external device having been coupled to the second detection pin, the control circuit assigns a first lighting-effect command to the first control pin and assigns a second lighting-effect command to the second control pin, and
the first light-emitting circuit displays a first lighting effect according to the first lighting-effect command, and the second light-emitting circuit displays a second lighting effect according to the second lighting-effect command.

12. The control system as claimed in claim 11, wherein the first lighting effect is synchronized with the second lighting effect.

13. The control system as claimed in claim 12, wherein the control circuit comprises:
a detection circuit detecting a voltage of the first detection pin to generate a first detection signal and detecting a voltage of the second detection pin to generate a second detection signal; and
a determination circuit determining whether the first external device is coupled to the first detection pin and determining whether the second external device is coupled to the second detection pin.

14. The control system as claimed in claim 13, wherein the control circuit further comprises:
a platform controller hub coupled to the determination circuit; and
a central processing unit (CPU) coupled to the platform controller hub,
wherein the determination circuit provides a connection status between the first external device and the first detection pin and a connection status between the second external device and second detection pin to the CPU via the platform controller hub.

15. The control system as claimed in claim 14, wherein the CPU accesses the first external device.

16. The control system as claimed in claim 14, further comprising:
a first slot configured to accommodate the first external device; and
a second slot configured to accommodate the second external device,
wherein the first detection pin is electrically connected to the first slot, and the second detection pin is electrically connected to the second slot.

17. The control system as claimed in claim 16, wherein the first slot and the second slot are memory slots.

18. The control system as claimed in claim 16, wherein the first slot comprises:
a first contact pad electrically connected to the first detection pin; and
a second contact pad electrically connected to the first control pin, wherein:
in response to the first external device being coupled to the first slot, the first contact pad is electrically connected to a first pin of the first external device, and the second contact pad is electrically connected to a second pin of the first external device.

19. The control system as claimed in claim 18, wherein the second slot comprises:
a third contact pad electrically connected to the second detection pin; and
a fourth contact pad electrically connected to the second control pin,
wherein:
in response to the second external device being coupled to the second slot, the third contact pad is electrically connected to a third pin of the second external device, and the fourth contact pad is electrically connected to a fourth pin of the second external device.

20. The control system as claimed in claim 19, further comprising:
a first resistor coupled to the first detection pin; and
a second resistor coupled to the second detection pin,
wherein the first pin is coupled to a third resistor, the third pin is coupled to a fourth resistor, the second pin is coupled to the first light-emitting circuit, and the fourth pin is coupled to the second light-emitting circuit.
